(19) United States
(12) Patent Application Publication
(10) Pub. No.: US 2007/0046421 A1
(43) Pub. Date: Mar. 1, 2007

(54) STRUCTURE AND METHOD FOR FORMING THIN FILM RESISTOR WITH TOPOGRAPHY CONTROLLED RESISTANCE DENSITY

(75) Inventors: Usha Gogineni, Fishkill, NY (US); Vidhya Ramachandran, Ossining, NY (US)

Correspondence Address: CANTOR COLBURN LLP - IBM FISHKILL, 55 GRIFFIN ROAD SOUTH, BLOOMFIELD, CT, 06002, US

(73) Assignee: INTERNATIONAL BUSINESS MACHINES CORPORATION, Armonk, NY (US)

(21) Appl. No.: 11/162,218

(22) Filed: Sep. 1, 2005

(51) Int. Cl. H01C 1/012

(52) U.S. Cl. 338/309

(57) ABSTRACT

A method for forming a thin film resistor includes forming a topographic feature on a semiconductor substrate, forming an isolation layer over the topographic feature, and forming a resistor film layer over the isolation layer. Portions of the resistor film layer are patterned and removed so as to form the thin film resistor at a desired length, the length extending at least in a vertical direction with respect to a horizontal plane of the semiconductor substrate

### BACKGROUND

The present invention relates generally to semiconductor device manufacturing, and, more particularly, to a structure and method for forming a thin film resistor with topography-controlled resistance density.

Thin film resistors are employed in many types of integrated circuits in order to implement a desired functionality of the circuit, such as the biasing of active devices, serving as voltage dividers, and assisting in impedance matching, etc. Typically, a thin film resistor is formed by deposition of a resistive material on a dielectric layer, and subsequently patterned to a desired size and shape. Often, a thin film resistor is further subjected to a heat treatment process (i.e., annealing) to improve its stability and to bring the resistance to a desired value.

In terms of rectangular block resistors, the resistance value (R) is in direct proportion to the length (L) of the rectangular block and is in inverse proportion to the cross-sectional area (A) of the rectangular block. Thus, resistance is calculated as R=ρ(L/A) where ρ is the resistivity of the material, L is the length of the resistor along the direction of the current and A is the cross sectional area of the resistor along the direction of the current (i.e., the width of the material multiplied by the thickness). Thus, for a given thickness, t, and resistor width, w, the resistance expression becomes R=ρ(L/t·w)

In the fabrication of semiconductor devices, there are several methods of manufacturing thin film resistors. For the most part, such techniques describe forming a planar resistor wherein the resistance value thereof is varied by changing the thickness and/or the planar geometry of the thin film. Where higher resistance values are desired for a given thin film resistor, the length of the resistor may be increased. However, this leads to a bigger circuit footprint in the x and/or y directions of the resistor plane. Alternatively, resistance can be increased by decreasing the thickness of the formed film material. Unfortunately, a decrease in film thickness beyond a certain point can lead to reduced reliability in the functionality thereof, as a result of self-heating.

Accordingly, it would be desirable to be able to form thin film resistors with a desired resistance in a manner that conserves planar device real estate, and that also provides an increased measure of reliability in terms of power dissipation and heat performance.

### SUMMARY

The foregoing discussed drawbacks and deficiencies of the prior art are overcome or alleviated by a method for forming a thin film resistor. In an exemplary embodiment, the method includes forming a topographic feature on a semiconductor substrate, forming an isolation layer over the topographic feature, and forming a resistor film layer over the isolation layer. Portions of the resistor film layer are patterned and removed so as to form the thin film resistor at a desired length, the length extending at least in a vertical direction with respect to a horizontal plane of the semiconductor substrate.

In another embodiment, a thin film resistor for a semiconductor device includes a topographic feature formed on a semiconductor substrate, an isolation layer formed over the topographic feature, and a resistor film layer formed over the isolation layer. The resistor film layer has portions thereof patterned and removed so as to form the thin film resistor at a desired length, the length extending at least in a vertical direction with respect to a horizontal plane of the semiconductor substrate.

### BRIEF DESCRIPTION OF THE DRAWINGS

Referring to the exemplary drawings wherein like elements are numbered alike in the several Figures:

FIGS. 1(a) through 1(f) illustrate a method for forming a topographic thin film resistive device in accordance with an embodiment of the invention; and

FIGS. 2(a) through 2(f) illustrate a method for forming a topographic thin film resistive device in accordance with an alternative embodiment of the invention.

### DETAILED DESCRIPTION

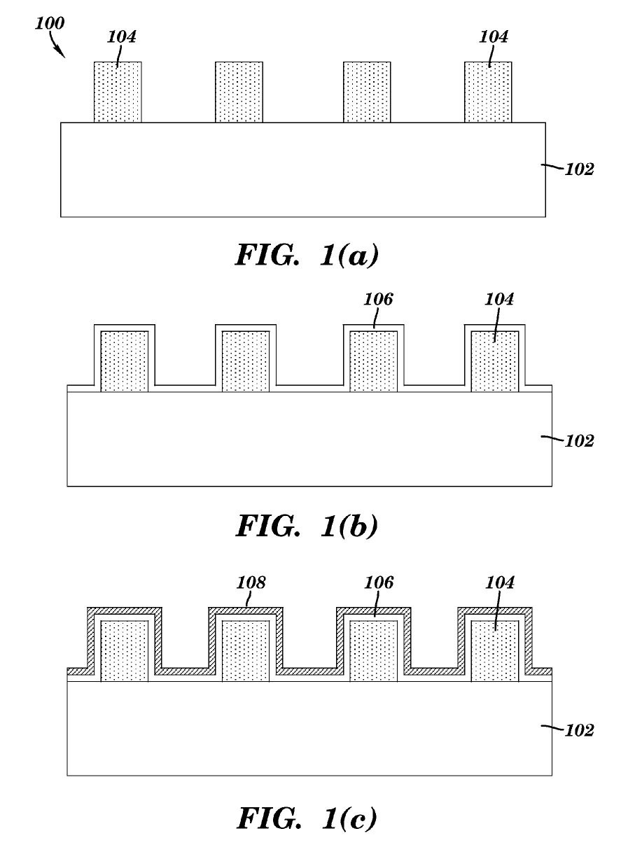

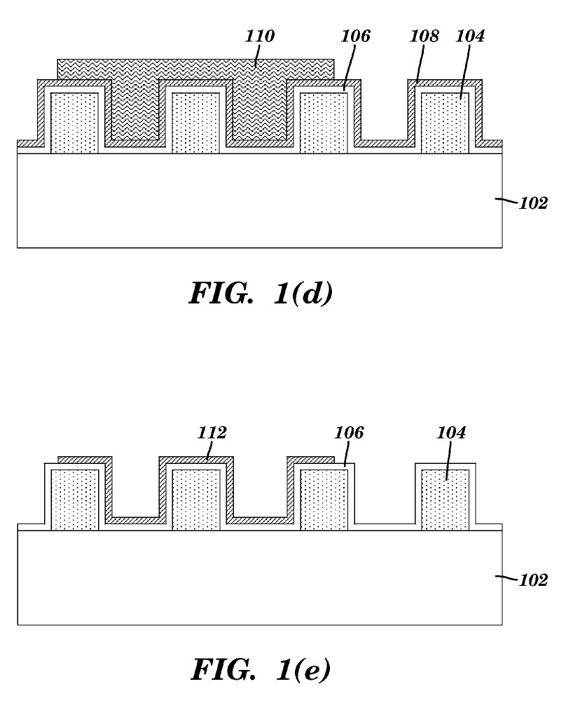

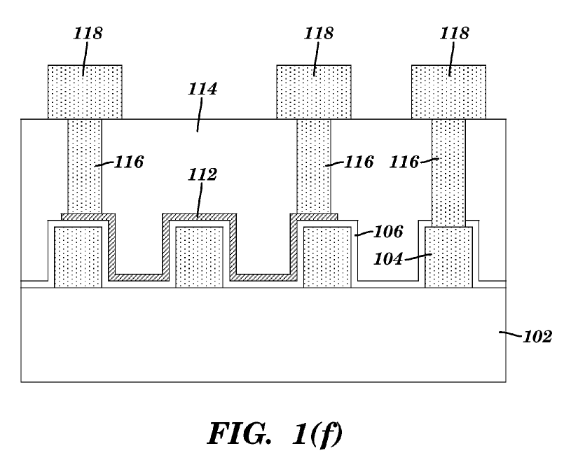

Disclosed herein is a structure and method for forming thin film resistors with a desired resistance in a manner that conserves planar device real estate, and that also provides a measure of reliability in terms of power dissipation and heat performance. Referring initially to FIGS. 1(a) through 1(f), there is shown a method for forming a topographic thin film resistive device in accordance with an embodiment of the invention. In the exemplary process flow depicted, the thin film resistor is formed over aluminum lines in a back end of line (BEOL) scheme. However, it will be appreciated that other metallization materials may also be used, and it will be further illustrated hereinafter that the topographic thin film resistor formation may be implemented at other locations within a semiconductor device.

As illustrated in FIG. 1(a) a semiconductor device 100 includes a substrate 102 having a plurality of metal lines 104 (e.g., aluminum) formed thereupon. Because the exemplary embodiment illustrates the semiconductor device 100 at a BEOL stage of processing, it will be recognized that the “substrate” 102 depicted in FIG. 1(a) represents not only (for example) a silicon or silicon-on-insulator substrate with various diffusion (doped regions) and other substrate-level structures formed therein, but also additional levels of wiring and various interlevel dielectric materials formed to this point. The topographic patterning of the lines 104 may be implemented by a subtractive process (e.g., metal deposition followed by lithographic patterning and etching) in the case of a metal such as aluminum.

In FIG. 1(b), an isolation layer 106 (such as an oxide or nitride layer for example) is conformally formed over the patterned lines 104 and will serve as an insulative barrier between the conductive lines 104 and the subsequent thin film resistor formed thereon, such that the entire length of the resistor will contribute to the resistance of the device. Then, as shown in FIG. 1(c), a resistor film layer 108 is formed over the isolation layer 106. The resistor film layer is selected from a suitable material such as polysilicon, TiN, TaN, W or Pt, for example, such that a patterned length thereof provides a desired resistance value.

Next, a patterned photoresist layer 110 is shown in FIG. 1(d), and defines the shape of the thin film resistor once the remaining exposed portions of the resistor film layer 108 are removed. The patterned thin film resistor 112 is shown in FIG. 1(e). Finally, FIG. 1(f) illustrates the addition of a subsequent wiring layer, including the formation of an interlevel dielectric layer 114 (which may be the same insulative material as the isolation layer 106 for example), conductive interconnect vias 116, and upper level metal lines 118. In particular, one of the upper lines 118 is shown electrically connected to one of the lower lines 114 (through a corresponding via 116), while two of the upper lines are electrically connected to opposite ends of the thin film resistor 112. In the illustrated embodiment, it is assumed that the etching process of the interlevel dielectric layer 114 is selective to the thin film resistor material during the definition of the vias 116. Alternatively, an etch stop layer (not shown) may also be formed after the resistor film layer 108 in FIG. 1(c).

Because the thin film resistor 112 undulates along with the topography of the metal lines 104, the resistance per unit planar area varies in accordance with the density of aluminum lines. As such, higher resistance values may be fit within a smaller planar area since the z-direction is used to increase the length of the resistor. More specifically, each metal line completely used to define resistor topography adds approximately 2t to the length of the resistor, where “t” is the thickness of the metal level in the z direction. Further, by using “n” metal lines beneath a unit length of resistor, the length of resistor is increased by 2tn with respect to a conventionally formed, planar resistor of corresponding x-y dimensions. Still another benefit of using metal (e.g., aluminum) lines to create z-direction topography for a thin film resistor act is that the close proximity thereto allows the lines to serve as a heat sink, thus enabling improved reliability and power performance. Moreover, the isolation layer further prevents the metal lines from decreasing the desired resistance of the thin film resistor due to direct contact therebetween.

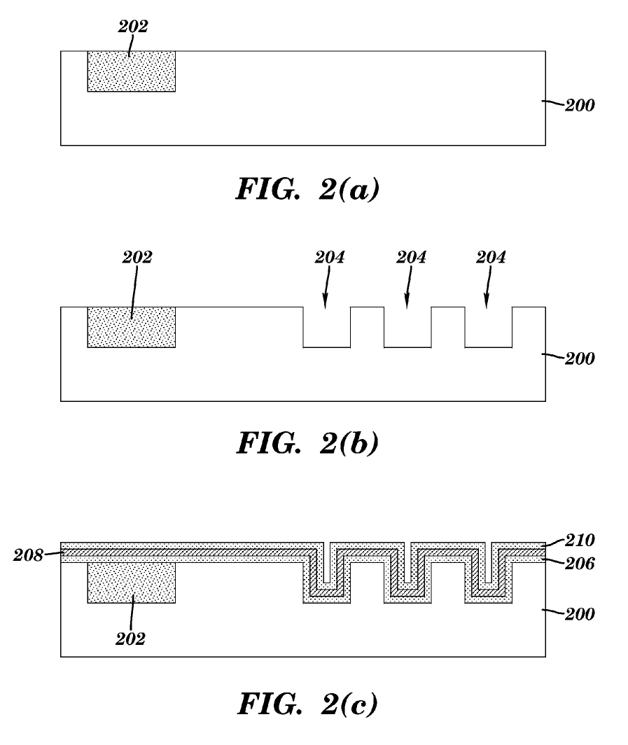

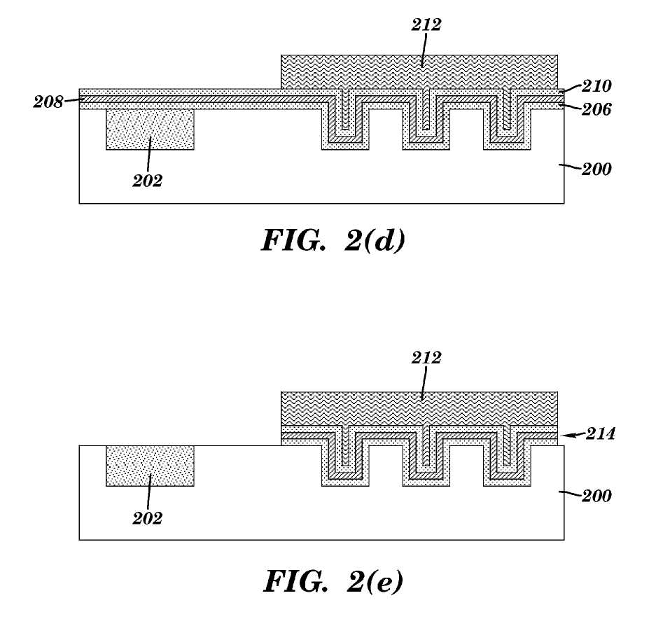

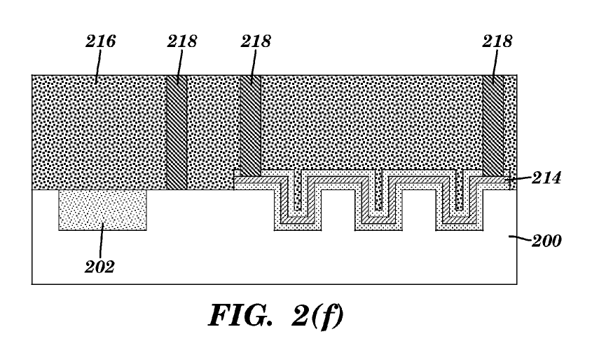

FIGS. 2(a) through 2(f) illustrate alternative embodiment of the thin film resistor formation of FIGS. 1(a) through 1(f), specifically demonstrating the applicability of the device and methodology to front end of line (FEOL) processing. In the particular embodiment depicted, the thin film resistor formation is implemented at the same level as a shallow trench isolation (STI), which will be recognized by one skilled in the art as an insulative barrier between active devices formed within a semiconductor substrate.

As shown in FIG. 2(a), a semiconductor substrate 200 (e.g., silicon, silicon on insulator) is provided with a filled shallow trench isolation 202 (e.g., an oxide of silicon). It should be noted that the front end active devices (such as transistors and capacitors) may or may not already be formed at this time by known techniques. In other words, any thin film resistor(s) at this level may be formed either before or after substrate device formation. Then, in FIG. 2(b), a plurality of trenches 204 are patterned within selected areas of the substrate 200 to define the resistor topography. The trenches may, for example, be formed in a manner similar to that used in the definition of the trench formed for STI 202. As shown in FIG. 2(c), a succession of layers are formed over the substrate 200 and within the trenches 204 so as to define a resistor stack, beginning with a resistor isolation film 206 (e.g., oxide, nitride, etc.) As is the case with the embodiment of FIG. 1, the isolation film 206 will prevent direct contact between the thin film resistor and the substrate 200 so that the entire length of the resistor contributes to the resistance of the device.

Following the formation of the isolation film layer 206, a resistor film layer 208 is then formed thereupon. The width of the trenches 204 and thickness of isolation film are such that a desired topography is still present when the resistor film is deposited. Again, the resistor film layer 208 may be selected from any suitable material including, but not limited to polysilicon, TiN, TaN, W or Pt, for example. Then, a resistor capping layer 210 is formed over the resistor film layer 208 so as to serve as an insulating, etch resistive material such as nitride, for example.

FIG. 2(d) illustrates the patterned photoresist layer 212 for defining the length of the thin film resistor. As will be noted from FIG. 2(e), both the isolation layer 206 and the capping layer 210 are etched along with the resistor film layer 208 in forming the resulting thin film resistor 214. Finally, as shown in FIG. 2(f), a first interlevel dielectric layer 216 is formed over the substrate 200, including the resistor film stack. A plurality of vias 218 are then formed, including those for connection to opposite ends of the resistor 214, as well as to devices formed on the substrate 206. For ease of illustration, conventional processes such as contact silicidation are not shown. It should also be appreciated that other metal interconnect processes, such as dual damascene methods, may also be employed in forming subsequent wiring structures.

While the invention has been described with reference to a preferred embodiment or embodiments, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims.

What is claimed is:

1. A method for forming a thin film resistor, the method comprising:
forming a topographic feature on a semiconductor substrate;
forming an isolation layer over said topographic feature;
forming a resistor film layer over said isolation layer; and
patterning and removing portions of said resistor film layer so as to form the thin film resistor at a desired length, said length extending at least in a vertical direction with respect to a horizontal plane of said semiconductor substrate.

2. The method of claim 1, wherein said isolation layer is formed so as to isolate lower surfaces of the thin film resistor from conductive portions of said semiconductor substrate.

3. The method of claim 1, wherein said forming a topographic feature on said semiconductor substrate further comprises defining one or more trenches within said semiconductor substrate.

4. The method of claim 4, wherein said trenches defined within said semiconductor substrate correspond to a structural level of said semiconductor substrate having one or more shallow trench isolations formed therein.

5. The method of claim 4, further comprising forming a capping layer over said resistor film layer.

6. The method of claim 5, wherein said isolation layer and said capping layer are also patterned and removed along with said resistor film layer.

7. The method of claim 1, wherein said forming a topographic feature on said semiconductor substrate further comprises forming one or more patterned metallic lines on said semiconductor substrate.

8. The method of claim 7, wherein said one or more patterned metallic lines correspond to aluminum back end of line processing.

9. The method of claim 1, wherein said isolation layer comprises one or more of an oxide layer and a nitride layer.

10. The method of claim 1, wherein said resistor film layer comprises one or more of polysilicon, TiN, TaN, W and Pt.

11. A thin film resistor for a semiconductor device, comprising:
a topographic feature formed on a semiconductor substrate;
an isolation layer formed over said topographic feature;
a resistor film layer formed over said isolation layer; and
said resistor film layer having portions thereof patterned and removed so as to form the thin film resistor at a desired length, said length extending at least in a vertical direction with respect to a horizontal plane of said semiconductor substrate.

12. The thin film resistor of claim 11, wherein said isolation layer is formed so as to isolate lower surfaces of the thin film resistor from conductive portions of said semiconductor substrate.

13. The thin film resistor of claim 11, wherein said topographic feature formed on said semiconductor substrate further comprises one or more trenches defined within said semiconductor substrate.

14. The thin film resistor of claim 4, wherein said trenches defined within said semiconductor substrate correspond to a structural level of said semiconductor substrate having one or more shallow trench isolations formed therein.

15. The thin film resistor of claim 14, further comprising a capping layer formed over said resistor film layer.

16. The thin film resistor of claim 15, wherein said isolation layer and said capping layer are also patterned and removed along with said resistor film layer.

17. The thin film resistor of claim 11, wherein said topographic feature formed on said semiconductor substrate further comprises one or more patterned metallic lines formed on said semiconductor substrate.

18. The thin film resistor of claim 17, wherein said one or more patterned metallic lines correspond to aluminum back end of line processing.

19. The thin film resistor of claim 11, wherein said isolation layer comprises one or more of an oxide layer and a nitride layer.

20. The thin film resistor of claim 11, wherein said resistor film layer comprises one or more of polysilicon, TiN, TaN, W and Pt.
